(19) United States
(12) Patent Application Publication
(10) Pub. No.: US 2013/0148075 A1
(43) Pub. Date: Jun. 13, 2013

(54) LIQUID CRYSTAL LENS AND MANUFACTURING METHOD THEREOF

(71) Applicants: Chia-Rong SHEU, Tainan City (TW); Che-Ju Hsu, Tainan City (TW)

(72) Inventors: Chia-Rong SHEU, Tainan City (TW); Che-Ju Hsu, Tainan City (TW)

(21) Appl. No.: 13/458,444

(22) Filed: Apr. 27, 2012

(30) Foreign Application Priority Data
Dec. 13, 2011 (TW) 100146045

(51) Int. Cl. G02F 1/13; H01L 21/00

(52) U.S. Cl. 349/200; 438/30

(57) ABSTRACT

A liquid crystal lens includes a first substrate, a second substrate, a first electrode layer, a second electrode layer and a liquid crystal layer. The second substrate is disposed opposite to the first substrate. The first electrode layer is disposed on the second substrate and has a blank region which is configured with no electrode. The second electrode layer is disposed on a surface of the first substrate which faces to the second substrate. The liquid crystal layer is disposed between the first substrate and the second substrate, and has a plurality of monomers and liquid crystal molecules. The monomers and the liquid crystal molecules form a macromolecule polymer network structure along the projection direction of the blank region, so that the liquid crystal lens has two focal lengths. A manufacturing method of the liquid crystal lens is also disclosed.

### CROSS REFERENCE TO RELATED APPLICATIONS

This Non-provisional application claims priority under 35 U.S.C. §119(a) on Patent Application No(s). 100146045 filed in Taiwan, Republic of China on Dec. 13, 2011, the entire contents of which are hereby incorporated by reference.

### BACKGROUND OF THE INVENTION

1. Field of Invention

The present invention relates to a liquid crystal lens and a manufacturing method thereof.

2. Related Art

Based on the progress of optical imaging technology, the lens module with variable focal lengths has become one of the favorite functions when the customers choose their smart phones, tablets, or UMPC. A conventional way to adjust the focal length in the lens module is achieved by means of mechanical movements of lenses. However, these driving devices used for mechanical movements and lens module usually occupy a certain space, so that it is difficult to achieve the miniaturization of lens module to equip with the electronic apparatuses (e.g. smart phones, tablets, or UMPC). In another way, the liquid crystal lenses can be used in the lens module, which variable focal lengths are achieved by means of ideal distributions of refractive indices with respect to the applied voltages.

The conventional liquid crystal lens has a spherical surface and contains a uniform liquid crystal layer. The liquid crystal lens further has a spherical electrode disposed on the spherical surface. When applying a voltage to the spherical electrode, the liquid crystal molecules will be reoriented to form an ideal distribution of refractive indices, so that the purpose of variable focal lengths in the liquid crystal lens is achieved with respect to the variously applied voltages.

Although the conventional liquid crystal lens can achieve the purpose of variable focal lengths, however, the manufacturing processes of the spherical liquid crystal lens as well as its spherical electrode are very complicated, and the conventional liquid crystal lens can still not achieve the function of tunable coaxial bifocals.

Therefore, it is an important subject to provide an easy way for the manufacturing processes of liquid crystal lenses, which are simultaneously capable of tunable coaxial bifocals, and a manufacturing method thereof.

### SUMMARY OF THE INVENTION

In view of the foregoing subject, an objective of the present invention is to provide a liquid crystal lens, which can be easily manufactured and able to provide the function of tunable coaxial bifocals, and a manufacturing method thereof.

To achieve the above objective, the present invention discloses a liquid crystal lens including a first substrate, a second substrate, a first electrode layer, a second electrode layer and a liquid crystal layer. The second substrate is disposed opposite to the first substrate. The first electrode layer is disposed on the second substrate and has a blank region which is configured with no electrode. The second electrode layer is disposed on a surface of the first substrate which faces to the second substrate. The liquid crystal layer is disposed between the first substrate and the second substrate, and has a plurality of monomers and liquid crystal molecules. The monomers and the liquid crystal molecules form a macromolecule polymer network structure along the projection direction of the blank region, so that the liquid crystal lens has two focal lengths.

In one embodiment, the second substrate has a first surface and a second surface disposed opposite to the first surface, the second surface faces to the first substrate, and the first electrode layer is disposed on the first surface or the second surface.

In one embodiment, the shape of the blank region in the projection direction comprises a circle.

In one embodiment, the monomers comprise reactive mesogenic monomers, and the liquid crystal molecules comprise nematic liquid crystal molecules.

In one embodiment, the macromolecule polymer network structure is formed via light irradiation.

In one embodiment, the properties of the liquid crystal molecules of the macromolecule polymer network structure are determined based on energy and time of light irradiation.

In one embodiment, when a voltage is applied to the first electrode layer and the second electrode layer, at least one of the focal lengths is changed to allow the two focal lengths to become one.

In one embodiment, when a voltage is applied to the first electrode layer and the second electrode layer, the two focal lengths are changed to allow the two focal lengths to become one.

In one embodiment, the liquid crystal lens is applied to a naked-eye 3D image display apparatus or synchronous access of a multilayer disc.

To achieve the above objective, the present invention also discloses a manufacturing method of a liquid crystal lens. The manufacturing method includes steps of: providing a first substrate and a second substrate disposed opposite to each other; disposing a first electrode layer on the second substrate and a second electrode layer on a surface of the first substrate which faces to the second substrate; mixing a plurality of monomers and a plurality of liquid crystal molecules to form a liquid crystal layer, which is disposed between the first substrate and the second substrate; applying a voltage to the first electrode layer and the second electrode layer so as to form an electric field between the first electrode layer and the second electrode layer; and disposing a mask over the second substrate, exposing to light for a certain time, and then removing the mask and the applied voltage.

In one embodiment, the second substrate has a first surface and a second surface disposed opposite to the first surface, the second surface faces to the first substrate, and the first electrode layer is disposed on the first surface or the second surface.

In one embodiment, the liquid crystal layer has an exposure region, the first electrode layer has a blank region configured with no electrode, and the area of the blank region is larger than that of the exposure region along a projection direction of the blank region.

In one embodiment, the shape of the blank region and the exposure region in the projection direction respectively comprise a circle.

In one embodiment, the monomers and the liquid crystal molecules form a macromolecule polymer network structure along the projection direction, and the characteristics of the liquid crystal molecules of the macromolecule polymer network structure are determined based on energy and time of the light irradiation.

In one embodiment, the monomers comprise reactive mesogenic monomers, and the liquid crystal molecules comprise nematic liquid crystal molecules.

In one embodiment, the applied voltage is 100 Vrms, the intensity of the light irradiation is 6 mW/cm², and the certain exposure time is 2 or 2.5 minutes.

In one embodiment, the liquid crystal lens has two focal lengths.

In one embodiment, when another voltage is applied to the first electrode layer and the second electrode layer, at least one of the focal lengths is changed to allow the two focal lengths to become one.

In one embodiment, when another voltage is applied to the first electrode layer and the second electrode layer, the two focal lengths are changed to allow the two focal lengths to become one.

As mentioned above, the liquid crystal layer of the liquid crystal lens of the present invention has a plurality of monomers and a plurality of liquid crystal molecules, which form a macromolecule polymer network structure along the projection direction of the blank region of the first electrode layer, so that the liquid crystal lens has two focal lengths. In addition, the manufacturing method of the liquid crystal lens of the present invention includes the simple steps of applying a voltage to the first and second electrode layers, disposing a mask over the second substrate, and exposing to light for a certain time for initiating the photo-polymerization reaction between the monomers and the liquid crystal molecules. Accordingly, the present invention can simplify the manufacturing processes of the liquid crystal lens, and achieve the function of tunable coaxial bifocals thereof.

### BRIEF DESCRIPTION OF THE DRAWINGS

The invention will become more fully understood from the detailed description and accompanying drawings, which are given for illustration only, and thus are not limitative of the present invention, and wherein:

FIGS. 1A and 1B are a sectional view and a top view of a liquid crystal lens according to a preferred embodiment of the present invention;

FIG. 2 is a flow chart showing a manufacturing method of the liquid crystal lens of the present invention;

FIGS. 3A to 3D are schematic diagrams showing the liquid crystal lens of the present invention during the manufacturing processes;

FIGS. 4A and 4B are schematic graphs showing the polarization interference fringes of the liquid crystal lenses of the present invention, which are not applied with voltage;

FIGS. 5A to 5D are schematic graphs showing the polarization interference fringes of the liquid crystal lens of the present invention when applying different voltages to the first and second electrode layers;

FIG. 5E is a schematic graph showing the variations of the focal lengths of the liquid crystal lens of the present invention when applying different voltages to the first and second electrode layers;

FIGS. 6A to 6D are schematic graphs showing the polarization interference fringes of another liquid crystal lens of the present invention when applying different voltages to the first and second electrode layers; and

FIG. 6E is a schematic graph showing the variations of the focal lengths of another liquid crystal lens of the present invention when applying different voltages to the first and second electrode layers.

### DETAILED DESCRIPTION OF THE INVENTION

The present invention will be apparent from the following detailed description, which proceeds with reference to the accompanying drawings, wherein the same references relate to the same elements.

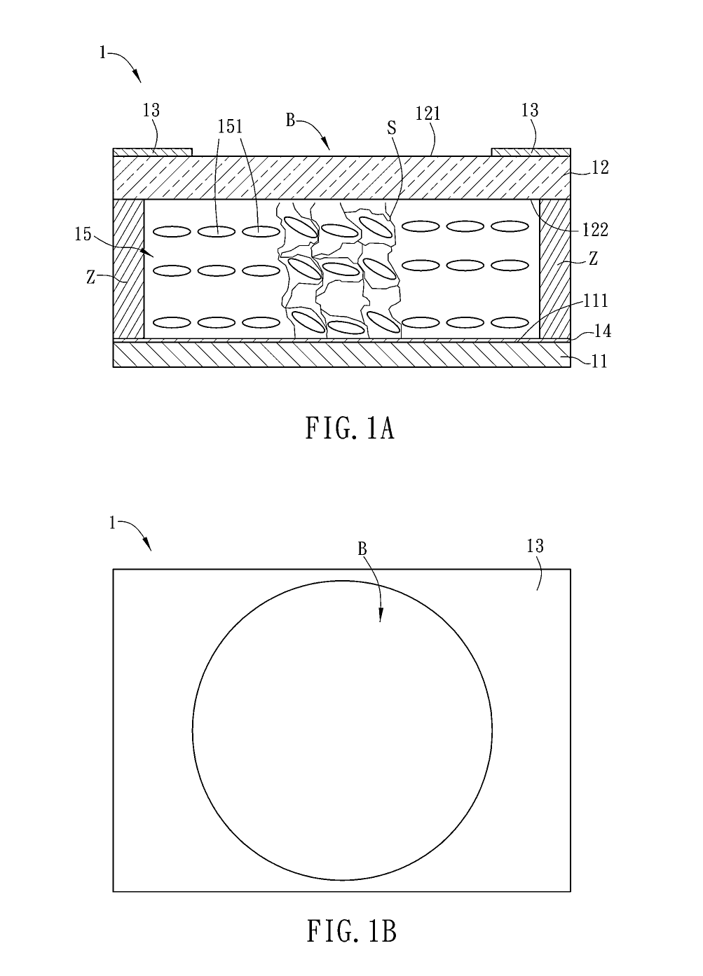

FIGS. 1A and 1B are a sectional view and a top view of a liquid crystal lens 1 according to a preferred embodiment of the present invention. The liquid crystal lens 1 includes a first substrate 11, a second substrate 12, a first electrode layer 13, a second electrode layer 14 and a liquid crystal layer 15.

The first substrate 11 and the second substrate 12 are disposed opposite to each other. In this embodiment, the first substrate 11 and the second substrate 12 are both glass substrates. The thickness of the first substrate 11 is about 0.7 mm, and the thickness of the second substrate 12 is about 1.4 mm. Of course, this is not to limit the thicknesses of the first and second substrates of the present invention, and they may be configured with different thicknesses.

The first electrode layer 13 is disposed on the second substrate 12. The second substrate 12 has a first surface 121 and a second surface 122 facing to the first substrate 11, and the first electrode layer 13 is disposed on the first surface 121 or the second surface 122. In this embodiment, the first electrode layer 13 is disposed on the first surface 121 (upper surface) of the second substrate 12 for example. In detailed, the first electrode layer 13 is a patterned electrode layer made of a metal layer or a transparent conductive layer. The material of the metal layer may include aluminum, and the material of the transparent conductive layer may include, for example but not limited to indium-zinc oxide (IZO), aluminum-zinc oxide (AZO), GZO, or zinc oxide (ZnO). In this case, the first electrode layer 13 is an aluminum metal layer.

Referring to FIG. 1B, the first electrode layer 13 has a blank region B which is configured with no electrode. In other words, the first electrode layer 13 is disposed on the first surface 121 of the second substrate 12, and not the entire first surface 121 is configured with the first electrode layer 13. In this case, the first surface 121 has a particular region that is “blank”, and no electrode is formed on this particular region (blank region B). In addition, the shape of the blank region B in the projection direction (top view direction) may include a circle (e.g. a 7 mm diameter circle). Of course, the blank region B may have different aspects such as circles with different diameters. To be noted, if the thicknesses of the first substrate 11 and the second substrate 12 are both, for example, 0.7 mm, and the diameter of the blank region B is smaller than 1 mm, the first electrode layer 13 can be also configured on the second surface 122 of the second substrate 12. Similarly, the second surface 122 may be not entirely configured with the electrode layer, and a blank region is remained thereon.

The second electrode layer 14 is disposed on a surface of the first substrate 11, which faces to the second substrate 12. In this case, the second electrode layer 14 is a transparent conductive layer disposed on the upper surface 111 of the first substrate 11.

The liquid crystal layer 15 is disposed between the first substrate 11 and the second substrate 12. In this embodiment, a spacer Z is provided between the first substrate 11 and the second substrate 12 and surrounding the liquid crystal layer 15, so that the liquid crystal layer 15 can be sandwiched between the first substrate 11 and the second substrate 12. In practice, the thickness of the liquid crystal layer 15 is about 125 μm.

The liquid crystal layer 15 has a plurality of monomers (not shown) and liquid crystal molecules 151. In this embodiment, the monomers include reactive mesogenic monomers (monomer #RM257, Merck), and the liquid crystal molecules 151 include nematic liquid crystal molecules (liquid crystal #E7, Merck). The reactive mesogenic monomer is photo-reactive. After irradiated by light, the reactive mesogenic monomers generate photo-polymerization with the liquid crystal molecules 151. The reactive mesogenic monomers and the liquid crystal molecules 151 are mixed to form the homogenously aligned liquid crystal layer 15.

In addition, the monomers and the liquid crystal molecules 151 of the liquid crystal layer 15 form a macromolecule polymer network structure S along the projection direction (top view direction) of the blank region B, so that the liquid crystal lens 1 has two focal lengths. The macromolecule polymer network structure S is formed by irradiating with UV light. In other words, in order to allow the liquid crystal lens 1 to provide two focal lengths, the liquid crystal molecules 151 and the reactive mesogenic monomers are well mixed, and injected between the first substrate 11 and the second substrate 12, and then the UV light is provided to irradiate the mixture along the projection direction of the blank region B. Accordingly, the liquid crystal molecules 151 and the reactive mesogenic monomers may generate photo-polymerization reaction to form the macromolecule polymer network structure S. In practice, the properties of the liquid crystal molecules 151 of the macromolecule polymer network structure S are determined based on the energy and time of the UV light.

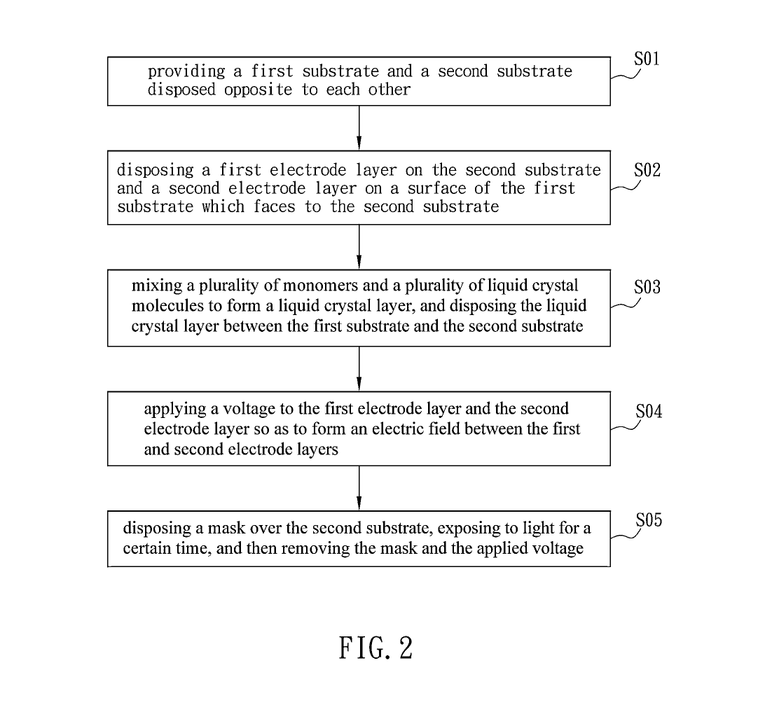

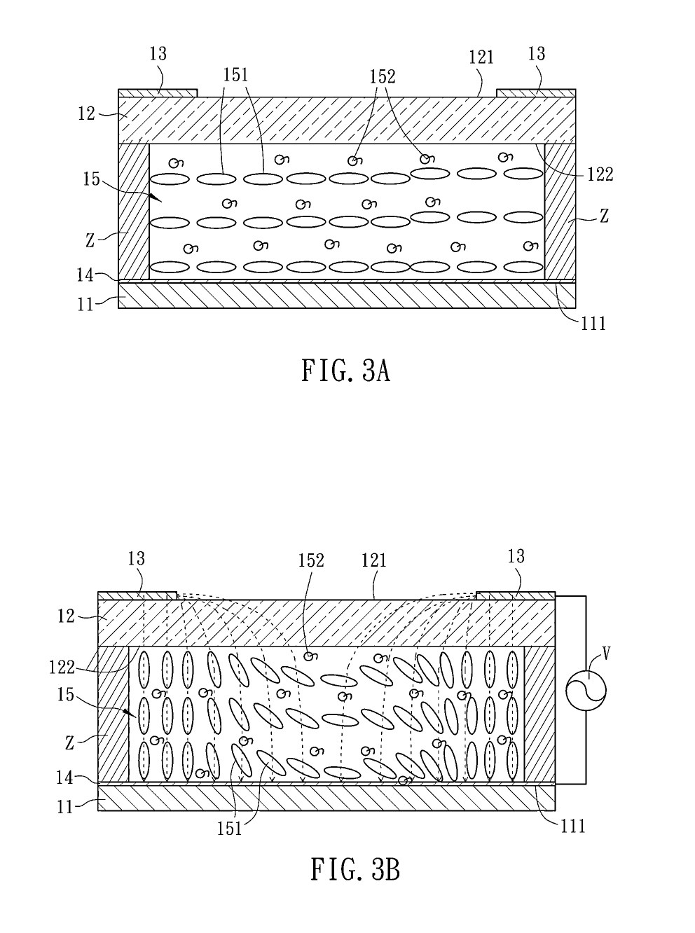

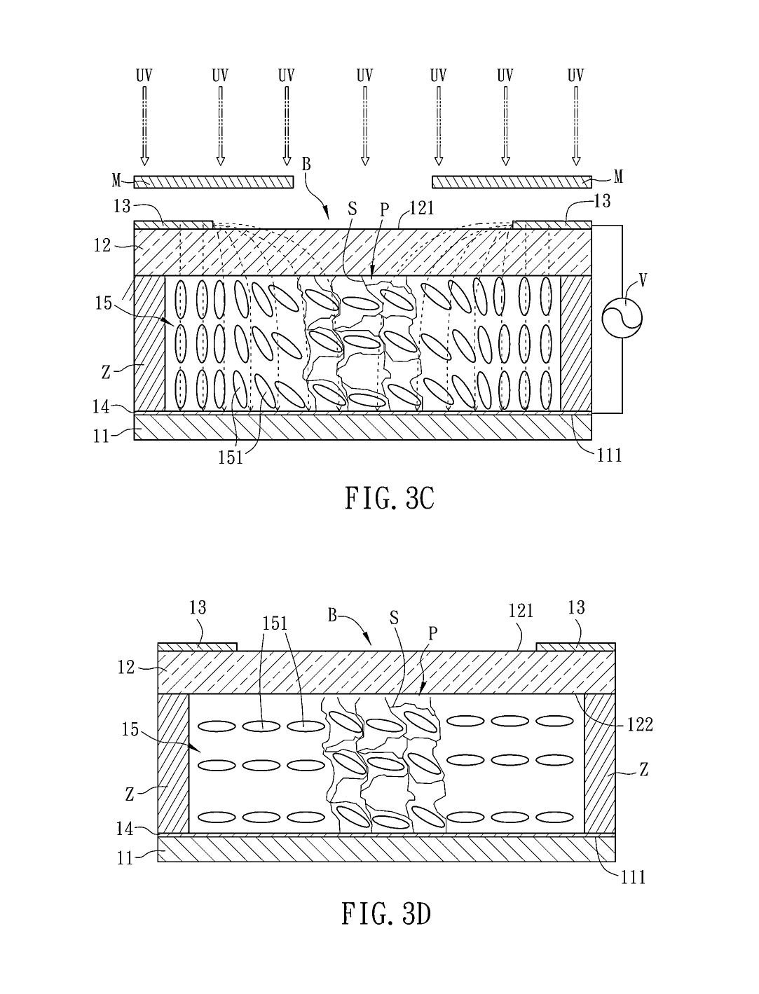

The detailed manufacturing processes and properties of the liquid crystal lens of the present invention will be further described hereinafter with reference to FIGS. 2 and 3A to 3D. Herein, FIG. 2 is a flow chart showing a manufacturing method of the liquid crystal lens of the present invention, and FIGS. 3A to 3D are schematic diagrams showing the liquid crystal lens of the present invention during the manufacturing processes.

Reference to FIG. 2, the manufacturing method of the liquid crystal lens of the present invention includes the following steps of providing a first substrate and a second substrate disposed opposite to each other (step S01); disposing a first electrode layer on the second substrate and a second electrode layer on a surface of the first substrate which faces to the second substrate (step S02); mixing a plurality of monomers and a plurality of liquid crystal molecules to form a liquid crystal layer, and disposing the liquid crystal layer between the first substrate and the second substrate (step S03); applying a voltage to the first electrode layer and the second electrode layer so as to form an electric field between the first and second electrode layers (step S04); and disposing a mask over the second substrate, exposing to light for a certain time, and then removing the mask and the applied voltage (step S05).

As shown in FIG. 3A, the step S01 is to provide a first substrate 11 and a second substrate 12. In this case, the second substrate 12 has a first surface 121 and a second surface 122 opposite to the first surface and facing the first substrate 11.

As shown in FIG. 3A, the step S02 is to dispose a first electrode layer 13 on the second substrate 12. In this case, the first electrode layer 13 is disposed on the first surface 121. Besides, the step S02 is also to dispose a second electrode layer 14 on the upper surface 111 of the first substrate 11, which faces to the second substrate 12.

As shown in FIG. 3A, the step S03 is to mix a plurality of liquid crystal molecules 151 and a plurality of monomers 152 to form a liquid crystal layer 15, and to dispose the liquid crystal layer 15 between the first substrate 11 and the second substrate 12. In this case, a spacer Z is provided between the first substrate 11 and the second substrate 12, thereby sandwiching the liquid crystal layer 15 between the first substrate 11 and the second substrate 12. The monomers 152 comprise reactive mesogenic monomers, and the liquid crystal molecules 151 comprise nematic liquid crystal molecules.

As shown in FIG. 3B, the step S04 is to apply a voltage V to the first electrode layer 13 and the second electrode layer 14 so as to form an electric field between the first electrode layer 13 and the second electrode layer 14. Herein, the RMS value (Vrms) of the voltage V is 100 Volts, and the electric field generated by the first electrode layer 13 and the second electrode layer 14 has gradient variations, so that the rotation angles of the liquid crystal molecules 151 also have gradient variations (see FIG. 3B).

As shown in FIG. 3C, the step S05 is to dispose a mask M over the second substrate 12, exposing to UV light for a certain time, and then removing the mask M and the applied voltage V. Accordingly, the liquid crystal lens 1 as shown in FIG. 3D can be obtained.

In the projection direction, the region of the liquid crystal layer 15 that is not blocked by the mask M is an exposure region P. In other words, the exposure region P is the region of the liquid crystal layer 15 that can be irradiated by the light UV. Besides, the first electrode layer 13 has a blank region B configured with no electrode. The shape of the blank region B and the exposure region P in the projection direction respectively comprise a circle. In this embodiment, the diameter of the blank region B is about 7 mm, and the diameter of the exposure region P is about 3.5 mm. That is, the area of the blank region B is larger than that of the exposure region P. The above mentioned diameters of the blank region B and the exposure region P are for illustrations only, and they can be modified in other aspects.

Referring to FIG. 3C, after irradiated by the light UV for a certain time, the monomers 152 (not shown in FIG. 3C) and the liquid crystal molecules 151 generate photo-polymerization reaction to form a macromolecule polymer network structure S. The characteristics of the liquid crystal molecules 151 of the macromolecule polymer network structure S are determined based on the energy and time of the irradiated light UV. If the energy is higher or the time is longer, more monomers 152 and liquid crystal molecules 151 generate photo-polymerization reaction to form the macromolecule polymer network structure S with different properties.

In addition, the electric field generated by the first electrode layer 13 and the second electrode layer 14 after applying the voltage V may have gradient variations. That is, the area closer to two ends can provide higher intensity of electric field, while the area closer to the middle can provide lower intensity of electric field. Reference to FIG. 3B, the rotation angles of the liquid crystal molecules 151 accordingly have gradient variations. That is, the liquid crystal molecules 151 located closer to two ends can have larger rotation angle, while the liquid crystal molecules 151 located closer to the middle can have smaller rotation angle.

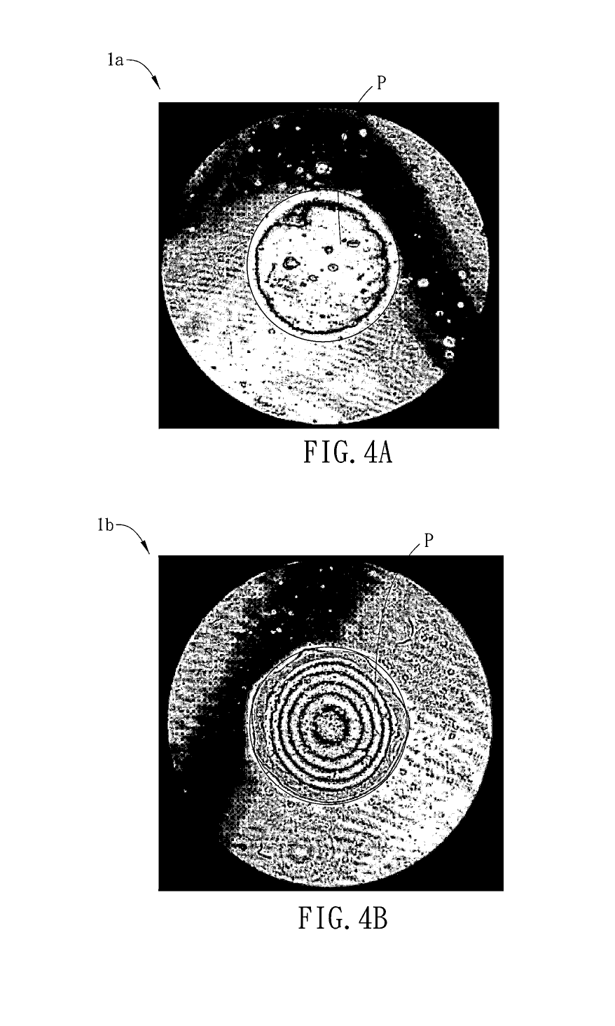

In this embodiment, the irradiated light UV is an ultraviolet ray, the intensity of the irradiated light is 6 mW/cm², and the exposure time is adjustable according to the actual demands. For example, after exposing to the light for 2 minutes, the mask M and the voltage V are removed so as to obtain the liquid crystal lens 1a (see FIG. 4A) according to an embodiment of the present invention. Alternatively, after exposing to the light for 2.5 minutes, the mask M and the voltage V are removed so as to obtain a liquid crystal lens 1b (see FIG. 4B) according to another embodiment of the present invention.

Since the exposure times (energies) are different, the liquid crystal lenses 1a and 1b are formed with the macromolecule polymer network structures S of different properties. To be noted, because the exposure time for manufacturing the liquid crystal lens 1b is longer, more monomers 152 and liquid crystal molecules 151 generate photo-polymerization reaction, so that the liquid crystal molecules 151 of the macromolecule polymer network structure S of the liquid crystal lens 1b may have fixed rotation angles. Otherwise, because the exposure time for manufacturing the liquid crystal lens 1a is shorter, less monomers 152 and liquid crystal molecules 151 generate photo-polymerization reaction, so that the rotation angles of the liquid crystal molecules 151 of the macromolecule polymer network structure S of the liquid crystal lens 1a may not be all fixed. Both the liquid crystal lenses 1a and 1b have two focal lengths. In specific, the RMS value of the voltage V, the light intensity, the exposure time can all be adjusted according to the actual demands. For example, in some aspects, if the intensity of the irradiated light UV is too strong, the exposure time can be properly decreased so as to manufacture the liquid crystal lens with the same property.

Other technical features of the manufacturing methods of the liquid crystal lenses 1a and 1b can refer to the previously mentioned embodiment, so the detailed descriptions thereof will be omitted.

FIGS. 4A and 4B are schematic graphs showing the polarization interference fringes of the liquid crystal lenses 1a and 1b of the present invention, which are not applied with voltages. The phase difference between two adjacent bright fringes of the polarization interference fringes (concentric circular interference fringes of FIG. 4B) is 2π. Moreover, more fringes represent larger phase change from the center to the periphery. The fringes are formed according to the liquid crystal molecules 151 arranged with gradient variation. To be noted, FIG. 4A shows a circle of dark fringe, and the area inside the circle of dark fringe represents the exposure region P of the liquid crystal layer 15 of the liquid crystal lens 1a. FIG. 4B shows several circles of dark and bright fringes, which represent the exposure region P of the liquid crystal layer 15 of the liquid crystal lens 1b. A part of the liquid crystal layer 15 within the exposure region P of the liquid crystal lens 1a/1b has a focal length F1 (not shown), and the other part of the liquid crystal layer 15 outside the exposure region P of the liquid crystal lens 1a/1b has another focal length F2 (not shown). The properties of the liquid crystal lenses 1a and 1b will be discussed hereinafter.

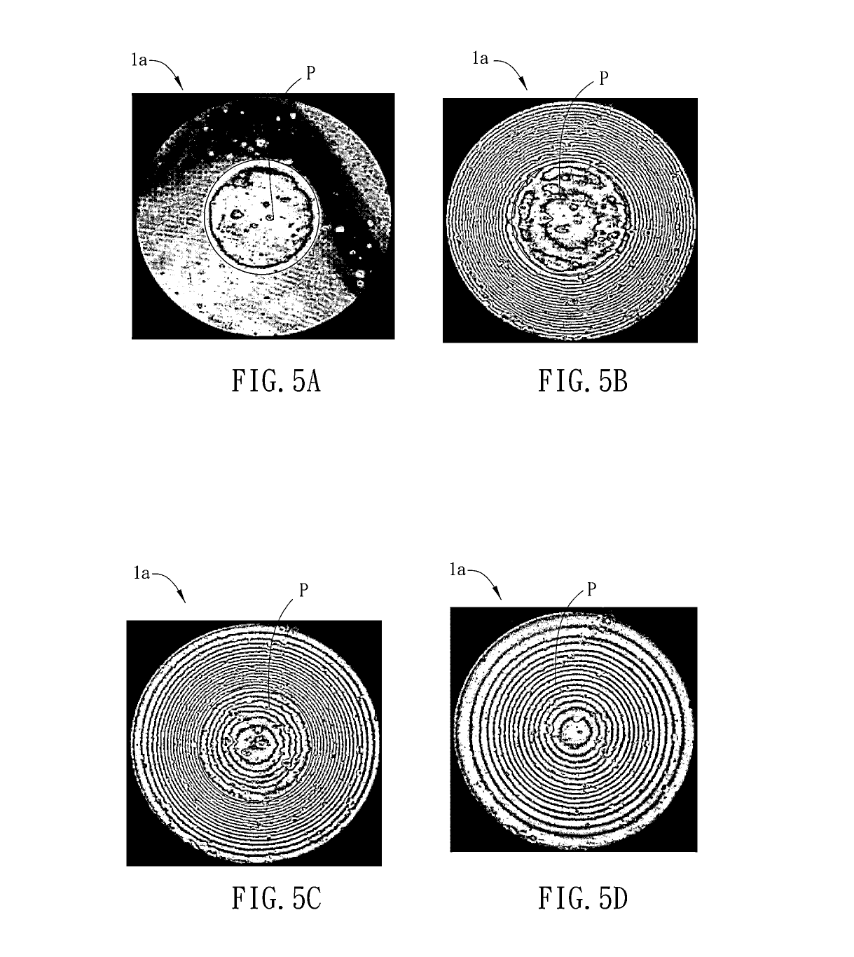

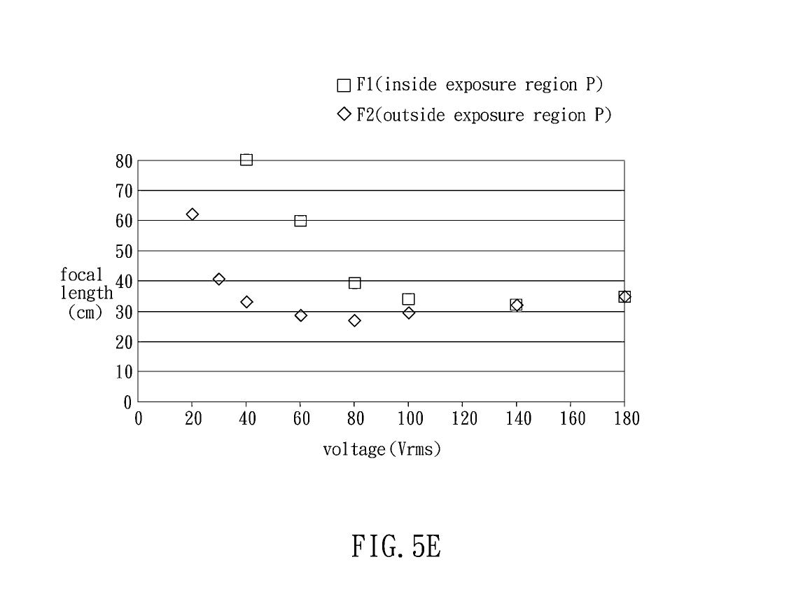

FIGS. 5A to 5D are schematic graphs showing the polarization interference fringes of the liquid crystal lens 1a when applying different voltages to the first electrode layer 13 and the second electrode layer 14, and FIG. 5E is a schematic graph showing the variations of the focal lengths F1 and F2 of the liquid crystal lens la when applying different voltages to the first electrode layer 13 and the second electrode layer 14.

The applied voltages are 0 Vrms for FIG. 5A, 40 Vrms for FIG. 5B, 100 Vrms for FIG. 5C, and 180 Vrms for FIG. 5D. Referring to FIGS. 5A to 5D, when applying different voltages to the first electrode layer 13 and the second electrode layer 14, the interference fringes of the liquid crystal lens 1a are changed, which means the focal lengths F1 and F2 are changed. Referring to FIG. 5E, the focal length F1 (squares) of the area inside the exposure region P and the focal length F2 (diamonds) of the area outside the exposure region P are applied with different voltages and thus changed. When the applied voltage is larger than or equal to 140 Vrms, the two focal lengths F1 and F2 become one so as to achieve the property of tunable coaxial bifocals.

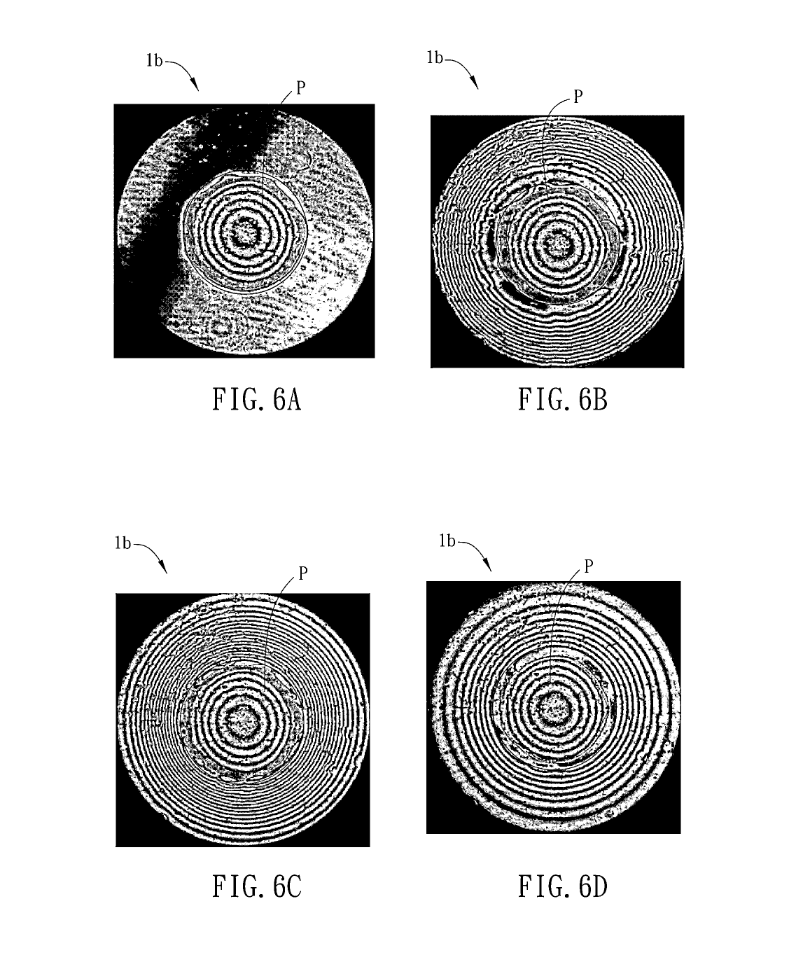

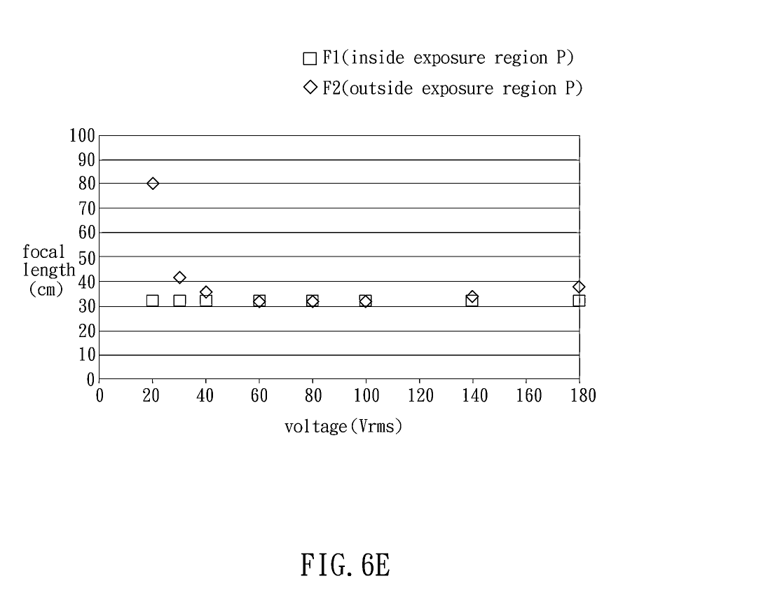

FIGS. 6A to 6D are schematic graphs showing the polarization interference fringes of the liquid crystal lens 1b when applying different voltages to the first electrode layer 13 and the second electrode layer 14, and FIG. 6E is a schematic graph showing the variations of the focal lengths F1 and F2 of the liquid crystal lens 1b when applying different voltages to the first electrode layer 13 and the second electrode layer 14.

The applied voltages are 0 Vrms for FIG. 6A, 30 Vrms for FIG. 6B, 100 Vrms for FIG. 6C, and 180 Vrms for FIG. 6D. Referring to FIGS. 6A to 6D, when applying different voltages to the first electrode layer 13 and the second electrode layer 14, the interference fringes outside the exposure region P of the liquid crystal lens 1b are changed, and the interference fringes inside the exposure region P of the liquid crystal lens 1b are mostly not changed. In specific, since the exposure time of the exposure region P of the liquid layer 15 of the liquid crystal lens 1b is longer, the rotation angles of the liquid crystal molecules 151 are fixed. Accordingly, when applying voltages to the first electrode layer 13 and the second electrode layer 14, the generated electric field only changes the focal length F2 of the area outside the exposure region P, and the focal length F1 is almost not changed. Referring to FIG. 6E, the focal length F1 (squares) of the area inside the exposure region P is not changed, and the focal length F2 (diamonds) of the area outside the exposure region P are changed due to the applied different voltages. When the applied voltage is larger than or equal to 60 Vrms, the two focal lengths F1 and F2 become one so as to achieve the property of tunable coaxial bifocals.

To be noted, the focal lengths F1 and F2 of the liquid crystal lens 1a can be separately adjusted, so that it can be applied to the naked-eye 3D image display apparatus of IP (Integral Photography) technology to improve the depth of field. Otherwise, in the liquid crystal lens 1b, the focal length F1 is fixed and the focal length F2 is adjustable, so that it can be applied to the synchronous access of a multilayer disc.

In summary, the liquid crystal layer of the liquid crystal lens of the present invention has a plurality of monomers and a plurality of liquid crystal molecules, which form a macromolecule polymer network structure along the projection direction of the blank region of the first electrode layer, so that the liquid crystal lens has two focal lengths. In addition, the manufacturing method of the liquid crystal lens of the present invention includes the simple steps of applying a voltage to the first and second electrode layers, disposing a mask over the second substrate, and exposing to light for a certain time for initiating the photo-polymerization reaction between the monomers and the liquid crystal molecules. Accordingly, the present invention can simplify the manufacturing processes of the liquid crystal lens, and achieve the function of tunable coaxial bifocals thereof.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A liquid crystal lens, comprising:
a first substrate;
a second substrate disposed opposite to the first substrate;
a first electrode layer disposed on the second substrate and having a blank region, which is configured with no electrode;
a second electrode layer disposed on a surface of the first substrate which faces to the second substrate; and
a liquid crystal layer disposed between the first substrate and the second substrate and having a plurality of monomers and a plurality of liquid crystal molecules, wherein the monomers and the liquid crystal molecules form a macromolecule polymer network structure along a projection direction of the blank region, so that the liquid crystal lens has two focal lengths.

2. The liquid crystal lens of claim 1, wherein the second substrate has a first surface and a second surface disposed opposite to the first surface, the second surface faces to the first substrate, and the first electrode layer is disposed on the first surface or the second surface.

3. The liquid crystal lens of claim 1, wherein the shape of the blank region in the projection direction comprises a circle.

4. The liquid crystal lens of claim 1, wherein the monomers comprise reactive mesogenic monomers, and the liquid crystal molecules comprise nematic liquid crystal molecules.

5. The liquid crystal lens of claim 1, wherein the macromolecule polymer network structure is formed via light irradiation.

6. The liquid crystal lens of claim 1, wherein the properties of the liquid crystal molecules of the macromolecule polymer network structure are determined based on energy and time of light irradiation.

7. The liquid crystal lens of claim 1, wherein when a voltage is applied to the first electrode layer and the second electrode layer, at least one of the focal lengths is changed to allow the two focal lengths to become one.

8. The liquid crystal lens of claim 1, wherein when a voltage is applied to the first electrode layer and the second electrode layer, the two focal lengths are changed to allow the two focal lengths to become one.

9. The liquid crystal lens of claim 1, wherein the liquid crystal lens is applied to a naked-eye 3D image display apparatus or synchronous access of a multilayer disc.

10. A manufacturing method of a liquid crystal lens, comprising steps of:
providing a first substrate and a second substrate disposed opposite to each other;
disposing a first electrode layer on the second substrate and a second electrode layer on a surface of the first substrate which faces to the second substrate;
mixing a plurality of monomers and a plurality of liquid crystal molecules to form a liquid crystal layer, which is disposed between the first substrate and the second substrate;
applying a voltage to the first electrode layer and the second electrode layer so as to form an electric field between the first electrode layer and the second electrode layer; and
disposing a mask over the second substrate, exposing to light for a certain time, and then removing the mask and the applied voltage.

11. The manufacturing method of claim 10, wherein the second substrate has a first surface and a second surface disposed opposite to the first surface, the second surface faces to the first substrate, and the first electrode layer is disposed on the first surface or the second surface.

12. The manufacturing method of claim 10, wherein the liquid crystal layer has an exposure region, the first electrode layer has a blank region configured with no electrode, and the area of the blank region is larger than that of the exposure region along a projection direction of the blank region.

13. The manufacturing method of claim 12, wherein the shape of the blank region and the exposure region in the projection direction respectively comprise a circle.

14. The manufacturing method of claim 12, wherein the monomers and the liquid crystal molecules form a macromolecule polymer network structure along the projection direction, and the characteristics of the liquid crystal molecules of the macromolecule polymer network structure are determined based on energy and time of the light irradiation.

15. The manufacturing method of claim 10, wherein the monomers comprise reactive mesogenic monomers, and the liquid crystal molecules comprise nematic liquid crystal molecules.

16. The manufacturing method of claim 10, wherein the applied voltage is 100 Vrms, the intensity of the light irradiation is 6 mW/cm², and the certain exposure time is 2 or 2.5 minutes.

17. The manufacturing method of claim 10, wherein the liquid crystal lens has two focal lengths.

18. The manufacturing method of claim 17, wherein when another voltage is applied to the first electrode layer and the second electrode layer, at least one of the focal lengths is changed to allow the two focal lengths to become one.

19. The manufacturing method of claim 17, wherein when another voltage is applied to the first electrode layer and the second electrode layer, the two focal lengths are changed to allow the two focal lengths to become one.
